(19) United States
(12) Patent Application Publication
(10) Pub. No.: US 2026/0045762 A1
(43) Pub. Date: Feb. 12, 2026

(54) SEMICONDUCTOR LASER ELEMENT AND METHOD OF MANUFACTURING SAME

(71) Applicants: SUMITOMO ELECTRIC INDUSTRIES, LTD., Osaka (JP); SUMITOMO ELECTRIC DEVICE INNOVATIONS, INC., Yokohama-shi (JP)

(72) Inventors: Daisuke INOUE, Osaka-shi (JP); Konosuke Aoyama, Yokohama-shi (JP)

(73) Assignees: SUMITOMO ELECTRIC INDUSTRIES, LTD., Osaka (JP); SUMITOMO ELECTRIC DEVICE INNOVATIONS, INC., Yokohama-shi (JP)

(21) Appl. No.: 19/289,809

(22) Filed: Aug. 4, 2025

(30) Foreign Application Priority Data
Aug. 7, 2024 (JP) 2024-130740

(51) Int. Cl. H01S 5/028; H01S 5/0625; H01S 5/12; H01S 5/50

(52) U.S. Cl. CPC H01S 5/0287; H01S 5/06258; H01S 5/1203; H01S 5/50

(57) ABSTRACT

A semiconductor laser element includes a laser section configured to cause light to perform laser oscillation, an amplification section configured to amplify the light, an active region extending to the laser section and the amplification section, a first anti-reflection coating provided on an end face of the laser section opposite to the amplification section with respect to the laser section, and a second anti-reflection coating provided on an end face of the amplification section opposite to the laser section with respect to the amplification section. In a plan view, an area of the active region in the amplification section is larger than an area of the active region in the laser section.

### CROSS REFERENCE TO RELATED APPLICATIONS

This application claims priority based on Japanese Patent Application No. 2024-130740 filed on Aug. 7, 2024, and the entire contents of the Japanese patent application are incorporated herein by reference.

### TECHNICAL FIELD

The present disclosure relates to a semiconductor laser element and a method of manufacturing the same.

### BACKGROUND

As a semiconductor laser element, a distributed feedback (DFB) laser element is known. For example, an element in which a DFB laser and a semiconductor optical amplifier (SOA) are integrated has been developed (see non-patent literature: H. Ishii et al. “Spectral Linewidth Reduction in Widely Wavelength Tunable DFB Laser Array” IEEE Journal of Selected Topics in Quantum Electronics, Vol. 15, No. 3, May/June 2009).

### SUMMARY

A semiconductor laser element according to the present disclosure includes a laser section configured to cause light to perform laser oscillation, an amplification section configured to amplify the light, an active region extending to the laser section and the amplification section, a first anti-reflection coating provided on an end face of the laser section opposite to the amplification section with respect to the laser section, and a second anti-reflection coating provided on an end face of the amplification section opposite to the laser section with respect to the amplification section. In a plan view, an area of the active region in the amplification section is larger than an area of the active region in the laser section.

### BRIEF DESCRIPTION OF THE DRAWINGS

FIG. 1 is a plan view illustrating a semiconductor laser element according to an embodiment.

FIG. 2 is a cross-sectional view illustrating a semiconductor laser element.

FIG. 3A is a cross-sectional view illustrating a semiconductor laser element.

FIG. 3B is a cross-sectional view illustrating a semiconductor laser element.

FIG. 4 is a flow chart illustrating a method of manufacturing a semiconductor laser element.

FIG. 5 is a plan view illustrating a method of manufacturing a semiconductor laser element.

FIG. 6 is a cross-sectional view illustrating a semiconductor laser element according to a comparative example.

FIG. 7A is an enlarged view near an end face.

FIG. 7B is an enlarged view near an end face.

FIG. 8 is a view illustrating a spectrum.

FIG. 9A is a diagram illustrating a power conversion efficiency of a laser section.

FIG. 9B is a diagram illustrating a power conversion efficiency of a laser section.

FIG. 10A is a diagram illustrating a power conversion efficiency of an entire semiconductor laser element.

FIG. 10B is a diagram illustrating a power conversion efficiency of an entire semiconductor laser element.

FIG. 11A is a diagram illustrating the relationship between a power input ratio and an optical output.

FIG. 11B is a diagram illustrating the relationship between a power input ratio and an optical output.

FIG. 12A is a diagram illustrating the relationship between a power input ratio and a power conversion efficiency.

FIG. 12B is a diagram illustrating the relationship between a power input ratio and a power conversion efficiency.

FIG. 13A is a diagram illustrating the relationship between a power input ratio and a power conversion efficiency.

FIG. 13B is a diagram illustrating the relationship between a power input ratio and a power conversion efficiency.

FIG. 13C is a diagram illustrating the relationship between a power input ratio and a power conversion efficiency.

FIG. 13D is a diagram illustrating the relationship between a power input ratio and a power conversion efficiency.

FIG. 13E is a diagram illustrating the relationship between a power input ratio and a power conversion efficiency.

FIG. 14A is a diagram illustrating the relationship between a power input ratio and a power conversion efficiency.

FIG. 14B is a diagram illustrating the relationship between a power input ratio and a power conversion efficiency.

FIG. 14C is a diagram illustrating the relationship between a power input ratio and a power conversion efficiency.

FIG. 14D is a diagram illustrating the relationship between a power input ratio and a power conversion efficiency.

FIG. 14E is a diagram illustrating the relationship between a power input ratio and a power conversion efficiency.

FIG. 15A is a diagram illustrating the relationship between a power input ratio and a power conversion efficiency.

FIG. 15B is a diagram illustrating the relationship between a power input ratio and a power conversion efficiency.

FIG. 15C is a diagram illustrating the relationship between a power input ratio and a power conversion efficiency.

FIG. 15D is a diagram illustrating the relationship between a power input ratio and a power conversion efficiency.

FIG. 15E is a diagram illustrating the relationship between a power input ratio and a power conversion efficiency.

FIG. 16A is a diagram illustrating the relationship between a power input ratio and a length of a portion of a mesa.

FIG. 16B is a diagram illustrating the relationship between a power input ratio and a length of a portion of a mesa.

FIG. 16C is a diagram illustrating the relationship between a power input ratio and a length of a portion of a mesa.

FIG. 16D is a diagram illustrating the relationship between a power input ratio and a length of a portion of a mesa.

FIG. 16E is a diagram illustrating the relationship between a power input ratio and a length of a portion of a mesa.

FIG. 17A is a diagram illustrating the relationship between a power input ratio and a length of a portion of a mesa.

FIG. 17B is a diagram illustrating the relationship between a power input ratio and a length of a portion of a mesa.

FIG. 17C is a diagram illustrating the relationship between a power input ratio and a length of a portion of a mesa.

FIG. 17D is a diagram illustrating the relationship between a power input ratio and a length of a portion of a mesa.

FIG. 17E is a diagram illustrating the relationship between a power input ratio and a length of a portion of a mesa.

FIG. 18A is a diagram illustrating the relationship between a power input ratio and a length of a portion of a mesa.

FIG. 18B is a diagram illustrating the relationship between a power input ratio and a length of a portion of a mesa.

FIG. 18C is a diagram illustrating the relationship between a power input ratio and a length of a portion of a mesa.

FIG. 18D is a diagram illustrating the relationship between a power input ratio and a length of a portion of a mesa.

FIG. 18E is a diagram illustrating the relationship between a power input ratio and a length of a portion of a mesa.

### DETAILED DESCRIPTION

Emitted light from an end face of the SOA is used for optical communication or the like. Emitted light from an end face of the DFB portion results in loss. In order to increase the efficiency, the output of the light emitted from the end face of the DFB portion may be lowered, while the optical output from the SOA may be made large. By providing a high-reflection coating on the end face of the DFB portion, the output from the end face of the DFB portion can be reduced, and the output from the SOA can be increased. However, since a wavelength of light varies according to the positional relationship between the high-reflection coating and a diffraction grating, the stability of the wavelength is reduced. Thus, an object is to provide a semiconductor laser element and a method of manufacturing the same, which can stabilize the wavelength of light and increase efficiency.

### DESCRIPTION OF EMBODIMENTS OF PRESENT DISCLOSURE

First, the contents of embodiments of the present disclosure will be listed and explained.
(1) A semiconductor laser element according to one aspect of the present disclosure includes a laser section configured to cause light to perform laser oscillation, an amplification section configured to amplify the light, an active region extending to the laser section and the amplification section, a first anti-reflection coating provided on an end face of the laser section opposite to the amplification section with respect to the laser section, and a second anti-reflection coating provided on an end face of the amplification section opposite to the laser section with respect to the amplification section. In a plan view, an area of the active region in the amplification section is larger than an area of the active region in the laser section. Since reflected light is less likely to be generated at an end face of the laser section, the influence of the reflected light on the wavelength of the emitted light from the amplification section is reduced. The wavelength can be controlled stably. Since a power input to the amplification section is larger than a power input to the laser section, efficiency can be increased.
(2) In the above (1), the area of the active region in the amplification section may be equal to or more than four times the area of the active region in the laser section. Since the power input to the amplification section is larger than the power input to the laser section, efficiency can be increased.
(3) In the above (1) or (2), the active region in the amplification section may be longer than the active region in the laser section. A width of the active region in the amplification section may be greater than a width of the active region in the laser section. Since the power input to the amplification section is larger than the power input to the laser section, efficiency can be increased.
(4) In any one of the above (1) to (3), the laser section may have a length of 400 μm to 1200 μm. The laser section operates stably. A loss of optical output is reduced and multimode is less likely to be generated.
(5) In any one of the above (1) to (4), a length of the active region in the laser section may be less than or equal to 0.6 times a length of the semiconductor laser element. The loss of light can be reduced. The amplification section becomes longer, and the efficiency is improved.
(6) In any one of the above (1) to (5), semiconductor laser element may further include an active layer provided in the laser section and the amplification section. The active region may be a mesa. The mesa may include an active layer and extend to the laser section and the amplification section. An area of the mesa in the amplification section is larger than an area of the mesa in the laser section. The power input to the mesa of the amplification section is larger than the power input to the mesa of the laser section. Efficiency is increased.
(7) In the above (6), the semiconductor laser element may further include a first semiconductor layer, the active layer, and a second semiconductor layer that are stacked in this order in the laser section and the amplification section. The first semiconductor layer may have a first conductivity type. The second semiconductor layer may have a second conductivity type. The first semiconductor layer and the active layer may be configured to form the mesa. The second semiconductor layer may be provided above the mesa. A pin junction is formed in the mesa, and current can flow through the active layer. Light is laser-oscillated in the laser section, and the light is amplified in the amplification section.
(8) In the above (6) or (7), the semiconductor laser element may further include an embedding layer provided on each of two sides of the mesa in the laser section and the amplification section. The efficiency is increased by intensively flowing the current to the mesa.
(9) In any one of the above (6) to (8), the semiconductor laser element may further include a first electrode provided in the laser section and overlapping a portion of the mesa provided in the laser section, and a second electrode provided in the amplification section and overlapping a portion of the mesa provided in the amplification section. The area of the mesa in the amplification section is larger than the area of the mesa in the laser section. The first electrode overlaps a wide portion of the mesa, and thus a large power is input. The second electrode overlaps a narrow portion of the mesa, and thus a small power is input. Efficiency is increased.
(10) In any one of the above (1) to (9), the light amplified by the amplification section may have an output of 200 mW or more. The higher the output, the higher the efficiency.
(11) A method of manufacturing a semiconductor laser element includes: designing a laser section configured to cause light to perform laser oscillation and an amplification section configured to amplify the light; forming the laser section and the amplification section based on the designing of the laser section and the amplification section; forming a first anti-reflection coating on an end face of the laser section opposite to the amplification section with respect to the laser section; forming a second anti-reflection coating on an end face of the amplification section opposite to the laser section with respect to the amplification section. The laser section and the amplification section include an active region. The designing is performed such that a power input to the active region in the amplification section is larger than a power input to the active region in the laser section. Since the reflected light is less likely to be generated at the end face of the laser section, the influence of the reflected light on the wavelength of the emitted light from the amplification section is reduced. The wavelength can be controlled stably. Since the power input to the amplification section is larger than the power input to the laser section, efficiency can be increased.

### Details of Embodiments of Present Disclosure

Specific examples of a semiconductor laser element and a method of manufacturing the same according to embodiments of the present disclosure will be described below with reference to the drawings. The present disclosure is not limited to these examples, but is defined by the scope of the claims, and is intended to include all modifications within the meaning and scope equivalent to the scope of the claims.

### Embodiment

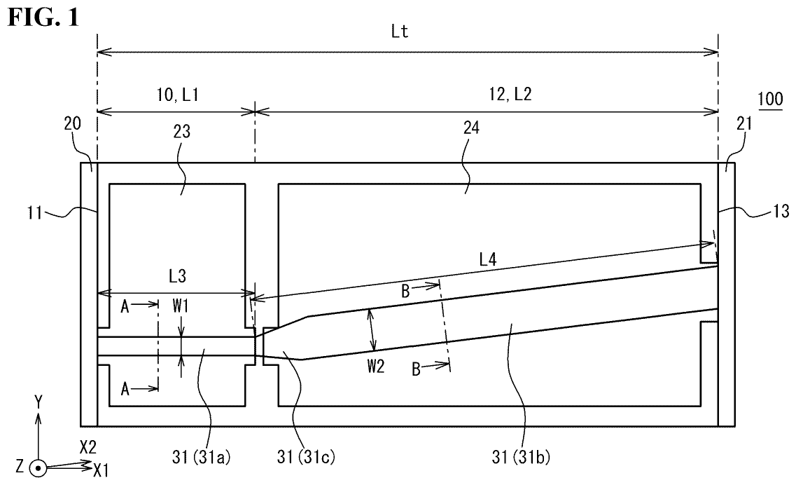

FIG. 1 is a plan view illustrating a semiconductor laser element 100 according to the embodiment.

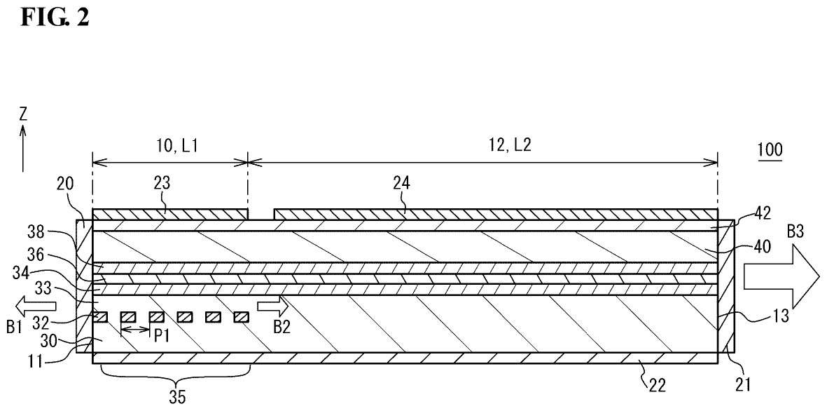

FIG. 2 is a cross-sectional view illustrating the semiconductor laser element 100.

As shown in FIG. 1 and FIG. 2, the semiconductor laser element 100 is an element in which a DFB laser and an SOA are integrated, and has a laser section 10 functioning as a DFB laser and an amplification section 12 functioning as an SOA. The laser section 10 and the amplification section 12 are adjacent to each other. The semiconductor laser element 100 may include elements other than the laser section 10 and the amplification section 12, but in the following examples, it is assumed to have the laser section 10 and the amplification section 12.

The laser section 10 extends in parallel to the X1-axis direction in FIG. 1. The amplification section 12 extends in parallel to the X2-axis direction. The Y-axis direction is a width direction of the semiconductor laser element 100. The Z-axis direction is a thickness direction of the semiconductor laser element 100. The X1, Y, and Z axes are orthogonal to each other. The X2 axis is parallel to the X1-Y plane and is inclined from the X1 axis. A length L1 of the laser section 10 in the X1-axis direction is, for example, 400 μm to 1200 μm. A length L2 of the amplification section 12 in the X1-axis direction is longer than the length L1. A length Lt of the semiconductor laser element 100 is the sum of the length L1 and the length L2, and is, for example, 1000 μm to 2500 μm.

The semiconductor laser element 100 has an end face 11 and an end face 13. The end face 11 is an end face of the laser section 10. The end face 13 is an end face of the amplification section 12. The end face 11 and the end face 13 are parallel to the YZ plane. The end face 11 and the end face 13 face each other. The semiconductor laser element 100 has a mesa 31 (active region). The mesa 31 extends from the end face 11 to the end face 13.

The semiconductor laser element 100 has an anti-reflection coating (AR coating) 20 and an anti-reflection coating 21. An anti-reflection coating 20 (first anti-reflection coating) is provided on the end face 11 and covers the end face 11. The anti-reflection coating 20 covers at least the end face of the mesa 31 in the end face 11. The anti-reflection coating 20 may cover the entire end face 11. The anti-reflection coating 20 may cover the end face of the mesa 31 and the periphery thereof in the end face 11. The anti-reflection coating 20 covers a range of the end face 11 where the intensity of light guided through the mesa 31 is distributed. The anti-reflection coating 21 (second anti-reflection coating) is provided on the end face 13 and covers the end face 13. The anti-reflection coating 21 covers at least the end face of the mesa 31 in the end face 13. The anti-reflection coating 21 may cover the entire end face 13. The anti-reflection coating 21 may cover the end face of the mesa 31 and the periphery thereof in the end face 13. The anti-reflection coating 21 covers a range of the end face 13 where the intensity of light guided through the mesa 31 is distributed. For light having a wavelength of around 1300 nm, the reflectance of each of the anti-reflection coating 20 and the anti-reflection coating 21 is less than 30%, such as 10% or less, or 1% or less. The anti-reflection coating includes a plurality of films, for example, a first film covering the end face and a second film covering the first film. Examples of the first film and the second film are shown below by the notation of first film/second film.
Titanium (IV) oxide (TiO₂)/silicon oxide (SiO₂)
Aluminum oxide (Al₂O₃)/undoped titanium oxide (i-TiO₂)
Titanium oxynitride (TION)/SiO₂
Tantalum oxide (Ta₂O₅)/SiO₂
   A structure in which the anti-reflection coating is provided on both the end face 11 and the end face 13 is sometimes referred to as AR/AR.

The mesa 31 extends from the end face 11 to the end face 13, and is provided in the laser section 10 and the amplification section 12. Light is generated in the mesa 31 and propagates along the mesa 31.

The mesa 31 includes a portion 31a and a portion 31b. The portion 31b includes a tapered portion 31c. The portion 31a is located in the laser section 10 and is parallel to the X1-axis direction. The width of the portion 31a in the direction perpendicular to the X1-axis direction is W1. The portion 31b is located in the amplification section 12 and is parallel to the X2-axis direction. The width of the portion 31b in a direction perpendicular to the X2-axis direction is W2. The width W2 is equal to the width W1 or more, and may be greater than the width W1. The width W1 is, for example, 2 μm. The width W2 is, for example, 4 μm. The tapered portion 31c has a tapered shape. The width of the tapered portion 31c becomes greater as the distance increases from the portion 31a.

A length of the portion 31a in the X1-axis direction is denoted by L3. A length of the portion 31b in the X2-axis direction is denoted by L4. The length L3 is equal to the length L1 of the laser section 10, and is, for example, 400 μm to 1200 μm. Since the portion 31b is inclined from the X1 axis, the length L4 is longer than the length L2 of the amplification section 12 in the X1 direction. The length L4 is, for example, 700 μm to 2100 μm. The lengths L3 and L4 are determined based on the power conversion efficiency, the optical output, and the like, and may take values outside the above range. The length L4 of the portion 31b may be longer than the length L3 of the portion 31a.

FIG. 2 shows a cross section including the mesa 31. As shown in FIG. 2, the semiconductor laser element 100 has a substrate 30 (first semiconductor layer), a semiconductor layer 32 (third semiconductor layer), a cladding layer 33 (first semiconductor layer), an optical confinement layer 34, an active layer 36, an optical confinement layer 38, a cladding layer 40 (second semiconductor layer), and a contact layer 42 (second semiconductor layer).

The cladding layer 33, the optical confinement layer 34, the active layer 36, the optical confinement layer 38, the cladding layer 40, and the contact layer 42 are stacked in this order in the Z-axis direction on one surface of the substrate 30.

In the laser section 10, a plurality of semiconductor layers 32 are periodically arranged in the X1-axis direction and embedded in the substrate 30 and the cladding layer 33. The cladding layer 33 and the semiconductor layer 32 are alternately arranged to form a diffraction grating 35. A pitch P1 of the diffraction grating 35 is, for example, 200 nm. The term “pitch” means a pitch between the adjacent semiconductor layers 32. The semiconductor layer 32 is not provided in the amplification section 12. That is, the diffraction grating 35 is provided in the laser section 10, and is not provided in the amplification section 12.

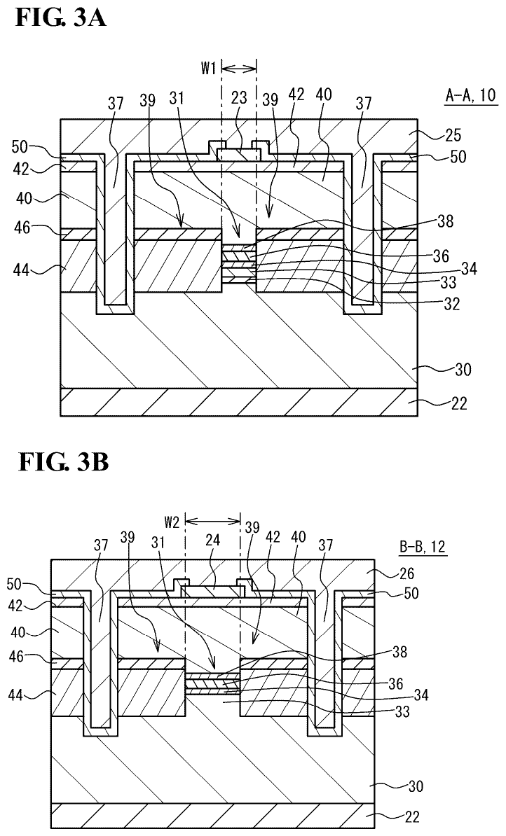

FIG. 3A and FIG. 3B are cross-sectional views illustrating the semiconductor laser element 100. FIG. 3A shows a cross section taken along a line A-A of FIG. 1. FIG. 3B shows a cross section taken along a line B-B of FIG. 1. As shown in FIG. 3A and FIG. 3B, the semiconductor laser element 100 has the mesa 31, a trench 37, and an embedding layer 39. The embedding layer 39 is provided on each of two sides of the mesa 31. The trench 37 is provided outside the embedding layer 39. The trench 37 and the embedding layer 39 extend along the mesa 31.

A center of the substrate 30 in the Y-axis direction protrudes in the Z-axis direction as compared to the portion of the substrate 30 outside the center. As shown in FIG. 3A, in the laser section 10, the semiconductor layer 32, the cladding layer 33, the optical confinement layer 34, the active layer 36, and the optical confinement layer 38 are stacked in the center of the substrate 30. As shown in FIG. 3B, in the amplification section 12, the cladding layer 33, the optical confinement layer 34, the active layer 36, and the optical confinement layer 38 are stacked on the center of the substrate 30. The layers from the center of the substrate 30 to the optical confinement layer 38 form the mesa 31.

A semiconductor layer 44 and a semiconductor layer 46 are stacked on each of two sides of the mesa 31 in the Y-axis direction, between the mesa 31 and the trench 37. The semiconductor layer 44 and the semiconductor layer 46 are embedded on each of two sides of the mesa 31 to form the embedding layer 39. The cladding layer 40 is provided on the mesa 31 and the semiconductor layer 46. The contact layer 42 is provided on the cladding layer 40.

As shown in FIG. 3A and FIG. 3B, the trench 37 is a portion recessed in the Z-axis direction, and extends through the layers from the contact layer 42 to the semiconductor layer 44 and extends to a part of the substrate 30. The semiconductor layer 44, the semiconductor layer 46, the cladding layer 40, and the contact layer 42 are provided outside the trench 37 in the Y-axis direction. The mesa 31, inside of the trench 37, and a portion outside the trench 37 are covered with an insulating film 50. The insulating film 50 has an opening above the mesa 31. The insulating film 50 is formed of an insulating material such as silicon oxide (SiO₂) and silicon nitride (SiN).

The substrate 30 is a semiconductor substrate and is formed of, for example, indium phosphide (n-InP) of an n-type (first conductivity type). The semiconductor layer 32 is formed of, for example, n-type indium gallium arsenide phosphide (n-InGaAsP). The emission wavelength of the semiconductor layer 32 is, for example, 1.0 μm to 1.15 μm. The cladding layer 33 is formed of, for example, n-InP. The substrate 30, the semiconductor layer 32, and the cladding layer 33 are doped with, for example, silicon (Si). The refractive index of the semiconductor layer 32 is different from the refractive index of each of the substrate 30 and the cladding layer 33.

The active layer 36 has a quantum well structure (MQW: Multi Quantum Well), and includes a plurality of well layers and a plurality of barrier layers. The plurality of well layers and the plurality of barrier layers are alternately stacked. The well layers and the barrier layers are formed of, for example, undoped InGaAsP. The emission wavelength is, for example, 1.25 μm to 1.6 μm. The optical confinement layer 34 and the optical confinement layer 38 are formed of, for example, InGaAsP. The refractive index of each of the optical confinement layer 34 and the optical confinement layer 38 is lower than the refractive index of the active layer 36 and higher than the refractive index of each of the cladding layer 33 and the cladding layer 40. The active layer 36, the optical confinement layer 34, and the optical confinement layer 38 form a separate confinement heterostructure (SCH).

The cladding layer 40 is formed of, for example, p-type (second conductivity type) indium phosphide (p-InP). The contact layer 42 has a p-InGaAs layer and a p-GaInAsPlayer. The InGaAs layer and the GaInAsP layer are stacked in this order on the cladding layer 40. The p-type semiconductor layer is doped with, for example, zinc (Zn).

The semiconductor layer 44 is formed of, for example, p-InP. The semiconductor layer 46 is formed of, for example, n-InP.

As shown in FIG. 2, the semiconductor laser element 100 has an electrode 22, an electrode 23 (first electrode), and an electrode 24 (second electrode). The electrode 22 is provided in the laser section 10 and the amplification section 12, and is in contact with a surface of the substrate 30 opposite to the active layer 36, and is electrically connected to the substrate 30.

As shown in FIG. 1 and FIG. 2, the electrode 23 and the electrode 24 are located on an upper surface of the semiconductor laser element 100. The electrode 23 is provided in the laser section 10 and overlaps the portion 31a of the mesa 31. The electrode 24 is provided in the amplification section 12 and overlaps the portion 31b of the mesa 31. The electrode 23 and the electrode 24 are separated from each other. The anti-reflection coating 20 may cover a part of the electrode 23 or a part of the electrode 22. Here, the part of the electrode is a portion of the electrode included in the end face 11. The anti-reflection coating 21 may cover a part of the electrode 24 or a part of the electrode 22. Here, the part of the electrode is a portion of the electrode included in the end face 13.

As shown in FIG. 3A, the electrode 23 is provided above the mesa 31 and on a surface of the contact layer 42 opposite to the cladding layer 40, and is in contact with the surface. A wiring layer 25 is provided on the electrode 23, and is also provided inside the trench 37 and in a portion outside the trench 37. The wiring layer 25 is in contact with the electrode 23 through the opening of the insulating film 50 above the mesa 31. The electrode 23 and the wiring layer 25 are electrically connected to the contact layer 42.

As shown in FIG. 3B, the electrode 24 is provided above the mesa 31 and on a surface of the contact layer 42 opposite to the cladding layer 40, and is in contact with the surface. A wiring layer 26 is provided on the electrode 24, and is also provided inside the trench 37 and in a portion outside the trench 37. The wiring layer 26 is in contact with the electrode 24 through the opening of the insulating film 50 above the mesa 31. The electrode 24 and the wiring layer 26 are electrically connected to the contact layer 42.

Each of the electrode 23 and the electrode 24 is formed of metal, and is, for example, a stacked body in which a gold (Au) layer, a tin (Sn) layer, and an Au layer are stacked in order from the side closest to the contact layer 42. Each of the wiring layer 25 and the wiring layer 26 is formed of, for example, Au. The electrode 22 is formed of metal.

The mesa 31 is the active region and includes the active layer 36. The p-type cladding layer 40 and the contact layer 42, the i-type active layer 36, the n-type cladding layer 33, and the substrate 30 are stacked at a position overlapping the mesa 31, and these semiconductor layers form a positive-intrinsic-negative (pin) junction. On each of two sides of the mesa 31, the p-type cladding layer 40, the n-type semiconductor layer 46, the p-type semiconductor layer 44, and the n-type substrate 30 are stacked, and a pnpn junction is formed. A current constriction structure is formed, and the current is likely to flow into the mesa 31 and less likely to flow out of the mesa 31.

When voltage is applied to the electrode 22 and the electrode 23, a current selectively flows through the mesa 31 of the laser section 10. When voltage is applied to the electrode 22 and the electrode 24, a current selectively flows through the mesa 31 of the amplification section 12. Carriers are injected into the active layer 36 and are combined, thereby generating light. The light propagates along the mesa 31 to each of two sides of the laser section 10, and laser oscillation occurs at a wavelength corresponding to the pitch of the diffraction grating 35.

The laser beam is indicated by an arrow in FIG. 2. Light propagating from the laser section 10 toward the end face 11 is denoted by B1. Light propagating from the laser section 10 toward the amplification section 12 is denoted by B2. Light propagating from the amplification section 12 toward the end face 13 is denoted by B3.

The laser beam B1 propagates from the laser section 10 to the end face 11, passes through the anti-reflection coating 20, and is emitted to the outside of the semiconductor laser element 100. The laser beam B2 enters the amplification section 12 from the laser section 10, and is amplified in the amplification section 12 to become the laser beam B3. The laser beam B3 propagates along the mesa 31 to the end face 13, passes through the anti-reflection coating 21, and is emitted to the outside of the semiconductor laser element 100. The intensity of the laser beam B2 is substantially equal to that of the laser beam B1. The laser beam B3 has been amplified by the amplification section 12, and thus has a higher intensity than the laser beams B1 and B2.

The semiconductor laser element 100 is used as, for example, a light source for optical communication. The emitted light B3 from the end face 13 is used for optical communication. The emitted light B1 from the end face 11 is not used for optical communication or the like.

The semiconductor laser element 100 is required to have an optical output of, for example, 200 mW or more, in addition to the stability of the wavelength. The amplification section 12 amplifies the output of the emitted light B3 to a target magnitude. In order to improve the quality of communication, it is required that the wavelength of the emitted light B3 does not change discontinuously during operation and that it is maintained at a target value. The semiconductor laser element 100 may be a wavelength tunable laser element. When a current flows through the heater (not shown), the heater generates heat, thereby heating the laser section 10. The refractive index of the diffraction grating 35 changes in accordance with the change in temperature. The wavelength of the laser beam is changed.

### (Manufacturing Method)

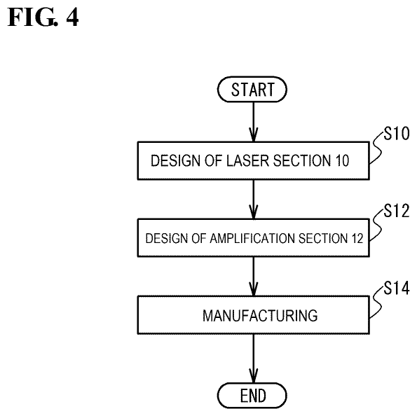

FIG. 4 is a flow chart illustrating a method of manufacturing the semiconductor laser element 100. The laser section 10 is designed (step S10). The amplification section 12 is designed (step S12). The element is manufactured based on the design (step S14).

In the design of the laser section 10, the pitch P1 of the diffraction grating 35, the resonator length L3, the width W1 of the portion 31a of the mesa 31, and the like are designed in consideration of the driving condition, the oscillation wavelength, and the like of the DFB laser. In the design of the amplification section 12, the length L4 and the width W2 of the portion 31b of the mesa 31 are designed in consideration of the driving condition, the target value of the optical output, and the like of the SOA. The design is performed such that a power Wsoa input to the mesa 31 of the amplification section 12 is larger than a power Wdfb input to the mesa 31 of the laser section 10 (steps S10 and S12). Specifically, the design is performed such that an area of the mesa 31 in the amplification section 12 is larger than an area of the mesa 31 in the laser section 10 in a plan view as shown in FIG. 1. The term “plan view” means a view in a direction (Z-axis direction) in which the semiconductor layers are stacked.

In the step S14, the following steps are performed. In the laser section 10, the semiconductor layer 32 is epitaxially grown on an upper surface of the substrate 30 by metal organic chemical vapor deposition (MOCVD). The semiconductor layer 32 of the laser section 10 is formed into an island shape by etching. The cladding layer 33 is epitaxially grown so as to embed the semiconductor layer 32. The diffraction grating 35 shown in FIG. 2 is formed. The optical confinement layer 34, the active layer 36, and the optical confinement layer 38 are epitaxially grown in this order in the laser section 10 and the amplification section 12. A p-type cladding layer is epitaxially grown on an upper surface of the optical confinement layer 38.

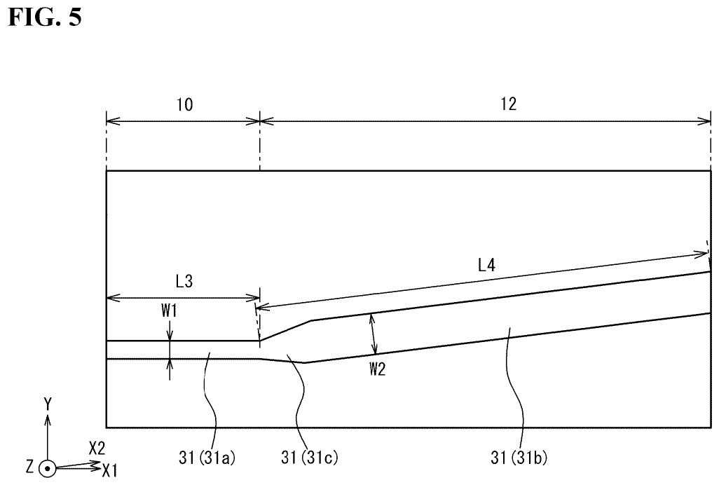

FIG. 5 is a plan view illustrating the method of manufacturing the semiconductor laser element 100. As shown in FIG. 5, the mesa 31 is formed by etching. The semiconductor layer 44 and the semiconductor layer 46 are embed and grown on each of two sides of the mesa 31. A p-type InP layer is epitaxially grown on the mesa 31 and the semiconductor layer 46. The p-type InP layer and the p-type cladding layer of the mesa 31 form the cladding layer 40. The contact layer 42 is epitaxially grown on an upper surface of the cladding layer 40.

On each of two sides of the mesa 31, etching is performed from the contact layer 42 to the part of the substrate 30 to form the trenches 37. The electrode 23 and the electrode 24 are formed on an upper surface of the contact layer 42 of the mesa 31 by, for example, vacuum deposition and lift-off.

For example, the insulating film 50 is formed by a plasma enhanced CVD (PECVD) method. The insulating film 50 covers the mesa 31, the inside of the trench 37, and the contact layer 42 outside the trench 37. An opening is formed in the insulating film 50 above the mesa 31. For example, the wiring layer 25 is formed on surfaces of the electrode 23 and the insulating film 50 by plating. The wiring layer 26 is formed on surfaces of the electrode 24 and the insulating film 50. A heater (not shown) is formed in the laser section 10 by vacuum deposition and lift-off. After the substrate 30 is polished from a rear surface, the electrode 22 is formed on the substrate 30.

A wafer is diced or cleaved to form chip-type elements. The end face 11 and the end face 13 are formed by the dicing or the cleavage. As shown in FIG. 1, the anti-reflection coating 20 is deposited on the end face 11. The anti-reflection coating 21 is deposited on the end face 13. The semiconductor laser element 100 is formed in the above manner. During the deposition of the anti-reflection coating 20 and the anti-reflection coating 21, the chip-type element is set in a deposition apparatus by using a jig. The range of the end face on which the anti-reflection coating is deposited can be changed by the shape of the jig. The range of the electrode on which the anti-reflection coating is formed can be changed by the shape of the jig.

### Comparative Example

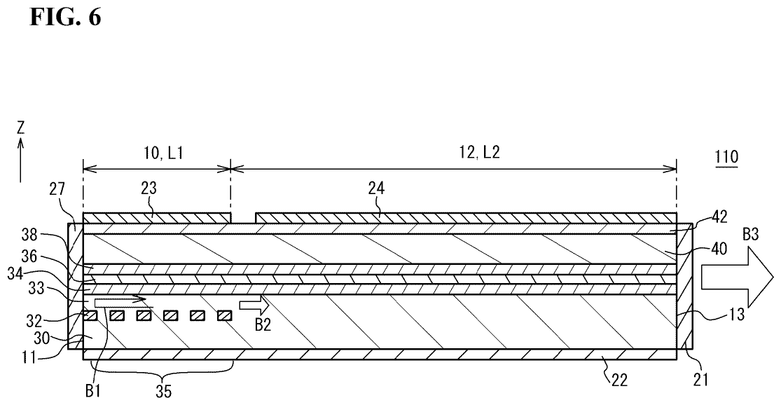

FIG. 6 is a cross-sectional view illustrating a semiconductor laser element 110 according to the comparative example. As shown in FIG. 6, a high-reflection coating (HR coating) 27 is provided on the end face 11 of the laser section 10. For light having a wavelength of around 1300 nm, the reflectance of a high-reflection coating 27 is higher than the reflectance of the anti-reflection coating, such as 70% or more, or 99% or more. A structure in which a high-reflection coating is provided on the end face 11, and an anti-reflection coating is provided on the end face 13 is sometimes referred to as HR/AR.

The reflectance of the high-reflection coating 27 is set to 70% or more. About 30% of the laser beam B1 is emitted to the outside from the end face 11. 70% or more of the laser beam B1 is reflected from the high-reflection coating 27. The reflected light propagates toward the amplification section 12. The laser beam B2 also propagates from the laser section 10 toward the amplification section 12. The reflected light and the light B2 are amplified in the amplification section 12 and emitted from the end face 13 as the emitted light B3. According to the comparative example, since the laser beam B1 is reflected, the loss of the optical output is reduced. However, the wavelength becomes unstable.

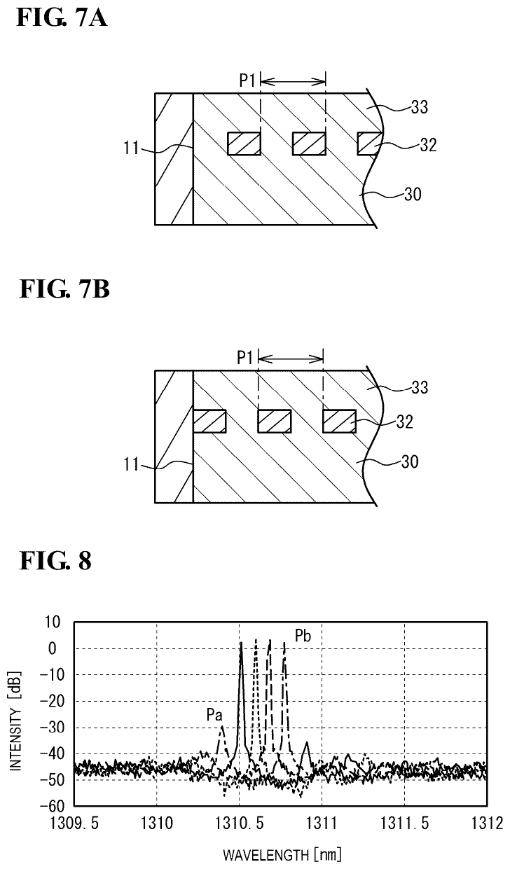

FIG. 7A and FIG. 7B are enlarged views near the end face 11, and show two different semiconductor laser elements. The end face 11 and the end face 13 of the semiconductor laser element are formed by dicing or cleavage. In both the embodiment and the comparative example, an error of about ±5 μm may occur in the position of dicing or cleavage. Positions of the end faces 11 vary among the plurality of semiconductor laser elements, and the positions of the end faces 11 with respect to the diffraction grating 35 in the semiconductor layer 32 of are changed.

In the comparative example, the laser beam B1 is reflected from the high-reflection coating 27, and reflected light is generated. The phase of the reflected light changes according to the positional relationship between the end face 11 and the diffraction grating 35. The wavelength of the composite wave of the reflected light and the laser beam B2 is changed by the change of the phase of the reflected light, and the wavelength of the emitted light B3 after amplification is also changed.

FIG. 8 is a view illustrating spectra of four semiconductor laser elements according to the comparative example. The horizontal axis represents the wavelength of light. The vertical axis represents the intensity of light. The spectra of four elements having different positions of the end face 11 and the diffraction grating 35 are represented by a solid line, a dotted line, a dashed line, and a one dot chain line. The pitch P1 of the diffraction grating 35 is set to 200 nm. As shown in FIG. 8, the wavelengths of the peaks are different from each other. When the position of the end face 11 changes in a range of about 5 μm, the wavelength of the peak changes by about 0.3 nm, and the wavelength of the plurality of elements do not coincide with each other. The spectrum of the one dot chain line has two peaks Pa and Pb. That is, resonance occurs at two different wavelengths. During the operation of the semiconductor laser element 110, a mode hop occurs, and the resonance state changes discontinuously. In the comparative example, the stability of the wavelength is reduced between multiple elements or even in a single element. Since an element having a wavelength different from the design value is regarded as a defective product, the yield is reduced.

In the embodiment, the anti-reflection coating 20 is provided on the end face 11. For example, about 99% of the laser beam B1 is emitted from the end face 11, and the reflected light is 1% or less of the laser beam B1. The intensity of the reflected light is smaller than that of the comparative example. A large portion of the light incident on the amplification section 12 is the emitted light B2 of the laser section 10. Thus, the influence of the reflected light on the wavelength of the emitted light B3 is reduced. Regardless of the position of the end face 11, the wavelength of the emitted light B3 is determined by the diffraction grating 35. The variation of the wavelength between the elements is reduced, and the mode hop is less likely to generated. The wavelength of the emitted light B3 is stabilized.

In the embodiment, the emitted light B1 in the laser section 10 passes through the anti-reflection coating 20 and emitted to the outside. About half of the light emitted from the laser section 10 results in loss. In order to increase the optical output, a power is input to the amplification section 12 to amplify light.

In order to increase the efficiency of the semiconductor laser element 100, it is only necessary that a power input to the laser section 10 is reduced and a power input to the amplification section 12 is increased. When the power input to the laser section 10 is reduced, the intensity of the emitted light B1 is reduced, and the loss of the optical output is reduced. The larger the power input to the amplification section 12, the more the optical output increases. In the design of FIG. 4 (steps S10 and S12), the design is performed such that the power Wsoa input to the mesa 31 of the amplification section 12 is larger than the power Wdfb input to the mesa 31 of the laser section 10. In the following, an example of the design will be described.

Table 1 shows examples of parameters of the semiconductor laser element 100 and the semiconductor laser element 110. DFB in Table 1 represents the laser section 10. SOA represents the amplification section 12.

TABLE 1

| | SEMICONDUCTOR | | |
|---|---|---|---|
| | LASER ELEMENT | 110 | 100 |
| DFB | THRESHOLD CURRENT | 2.4 | 2.4 |
| | DENSITY [kA/cm⁻²] | | |
| | BIAS CURRENT | 15 × Ith | 15 × Ith |
| | L3 [μm] | 400 to 1200 | 400 to 1200 |
| | RESISTANCE AT | 1.2 | 1.2 |
| | L3 = 800 μm [Ω] | | |
| | SLOPE EFFICIENCY [W/A] | 0.4 | 0.2 |
| | DRIVING POWER Wdfb [W] | | |
| SOA | POWER CONVERSION | 25 | 25 |
| | EFFICIENCY PCEsoa [%] | | |
| | DRIVING POWER Wsoa [W] | | |
| | OPTICAL OUTPUT[W] | 0 to 0.7 | 0 to 0.7 |

As shown in Table 1, in both the semiconductor laser element 110 according to the comparative example and the semiconductor laser element 100 according to the embodiment, the threshold current densities of the laser sections 10 exhibit 2.4 kA/cm⁻². A bias current input to the laser section 10 is 15 times the threshold current Ith (15×Ith). The length (resonator length) L3 of the mesa 31 of the laser section 10 changed from 400 μm to 1200 μm in increments of 200 μm. The electrical resistance of the laser section 10 is 1.2 Ω when the resonator length L3 is 800 μm. The slope efficiency is set to different values depending on the HR/AR structure and the AR/AR structure. The slope efficiency of the laser section 10 of the semiconductor laser element 110 is 0.4 W/A. The slope efficiency of the laser section 10 of the semiconductor laser element 100 is 0.2 W/A. The driving power Wdfb of the laser section 10 is determined according to the optical output.

In both the comparative example and the embodiment, a power conversion efficiency PCEsoa in the amplification section 12 is set to 25%. The term “power conversion efficiency” means a ratio of optical output to input power. The driving power Wsoa of the amplification section 12 is determined according to the optical output. The optical output from the amplification section 12 is in the range from 0 W to 0.7 W.

A power conversion efficiency PCEdfb of the laser section 10 and a power conversion efficiency PCEall of the entire semiconductor laser element are calculated in both the comparative example and the embodiment using the parameters of Table 1. The power conversion efficiency PCEdfb of the laser section 10 is expressed by Equation (1). PCEdfb=Pdfb/Wdfb (1) Pdfb is the optical output of the light B2 traveling from the laser section 10 to the amplification section 12. The power conversion efficiency PCEsoa of the amplification section 12 is expressed by Equation (2) and is fixed to 25% as shown in Table 1. Psoa is the optical output of the light B3 emitted from the amplification section 12 to the outside of the end face 13. PCEsoa=(Psoa−Pdfb)/Wsoa (2)

The power conversion efficiency PCEall of the entire semiconductor laser element is expressed by Equation (3). PCEall=Psoa/(Wdfb+Wsoa) (3)

A power input ratio Wr between the amplification section 12 and the laser section 10 is expressed by Equation (4). Wr=Wsoa/Wdfb (4)

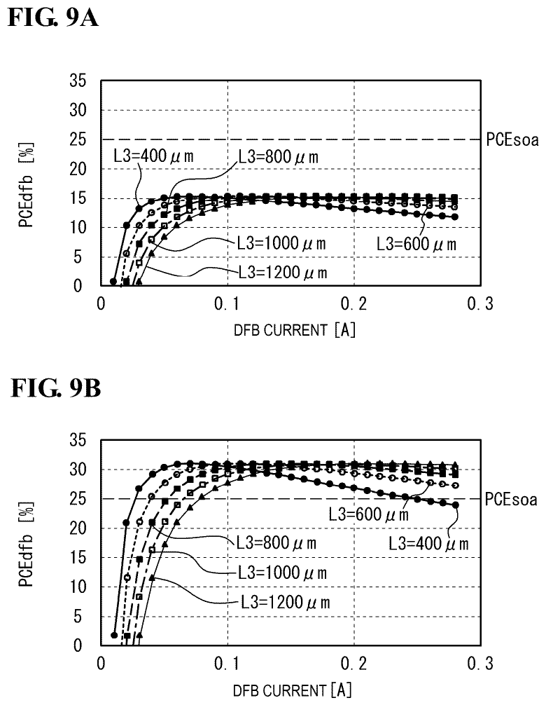

FIG. 9A and FIG. 9B are diagrams illustrating the power conversion efficiency of the laser section 10. The horizontal axis represents the current (DFB current) flowing through the mesa 31 of the laser section 10. The vertical axis represents the power conversion efficiency PCEdfb of the laser section 10. In FIG. 9A to FIG. 11B, the black circle and the thick solid line represent an example in which the length L3 (resonator length) of the mesa 31 in the laser section 10 is 400 μm. The white circle and the dotted line represent an example in which the resonator length L3 is 600 μm. The black square and dashed line represent an example in which the resonator length L3 is 800 μm. The white square and the one dot chain line represent an example in which the resonator length L3 is 1000 μm. The triangle and the thin solid line represent an example in which the resonator length L3 is 1200 μm.

FIG. 9A shows the power conversion efficiency PCEdfb in the embodiment. As shown in FIG. 9A, in the embodiment, the power conversion efficiency PCEdfb of the laser section 10 is lower than the power conversion efficiency PCEsoa (25%) of the amplification section 12. The power conversion efficiency PCEdfb is about 15% at the maximum for any value of the resonator length L3. FIG. 9B shows the power conversion efficiency PCEdfb in the comparative example. As shown in FIG. 9B, in the comparative example, the power conversion efficiency PCEdfb of the laser section 10 may take a value higher than the power conversion efficiency PCEsoa of the amplification section 12, and is about 30% at the maximum. In FIG. 9A and FIG. 9B, when the current is about 0.1 A or less, the shorter the resonator length L3, the higher the power conversion efficiency PCEdfb. When the current is large, the power conversion efficiency PCEdfb is higher as the resonator length L3 is longer.

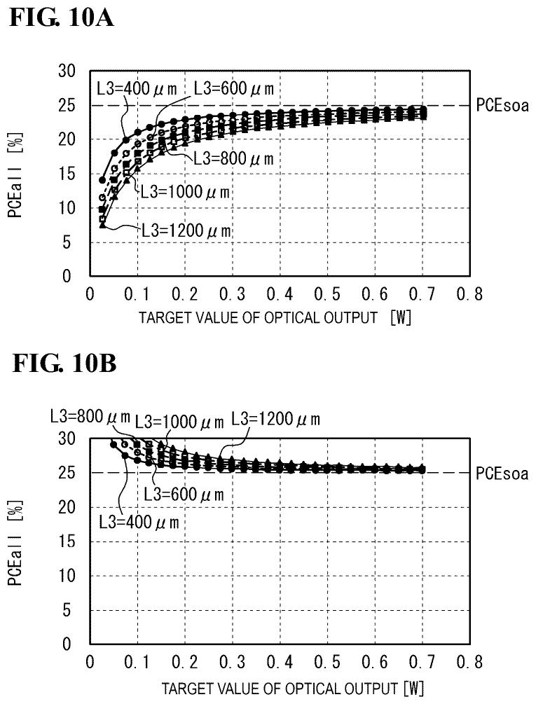

FIG. 10A and FIG. 10B are diagrams illustrating the power conversion efficiency PCEall of the entire semiconductor laser element. The horizontal axis represents the target value of the optical output from the amplification section 12. The vertical axis represents the power conversion efficiency PCEall of the entire semiconductor laser element.

FIG. 10A shows a power conversion efficiency PCEall in the embodiment. As shown in FIG. 10A, in the embodiment, the power conversion efficiency PCEall of the entire element is lower than the power conversion efficiency PCEsoa (25%) of the amplification section 12. For the same optical output, the shorter the resonator length L3, the higher the power conversion efficiency PCEall. At any value of the resonator length L3, the larger the optical output is, the higher the power conversion efficiency PCEall becomes, and the power conversion efficiency PCEall of the entire element approaches the power conversion efficiency PCEsoa of the amplification section 12.

FIG. 10B shows the power conversion efficiency PCEall in the comparative example. In the comparative example, the power conversion efficiency PCEall of the entire element is higher than the power conversion efficiency PCEsoa of the amplification section 12. For the same optical output, the longer the resonator length L3, the higher the power conversion efficiency PCEall. At any value of the resonator length L3, the larger the optical output is, the lower the power conversion efficiency PCEall becomes, and the power conversion efficiency PCEall of the entire element approaches the power conversion efficiency PCEsoa of the amplification section 12.

FIG. 11A and FIG. 11B are diagrams illustrating the relationship between the power input ratio Wr and the optical output. The horizontal axis represents the power input ratio Wr (=Wsoa/Wdfb). The vertical axis represents the target value of the optical output from the amplification section 12. FIG. 11A shows the embodiment. FIG. 11B shows the comparative example. As shown in FIG. 11A and FIG. 11B, the optical output is proportional to the power input ratio Wr at the same resonator length L3. The larger the target optical output, the greater the power input ratio Wr. In other words, by increasing the power input ratio Wr, a high optical output can be obtained. At a constant optical output, the shorter the resonator length L3, the greater the power input ratio Wr.

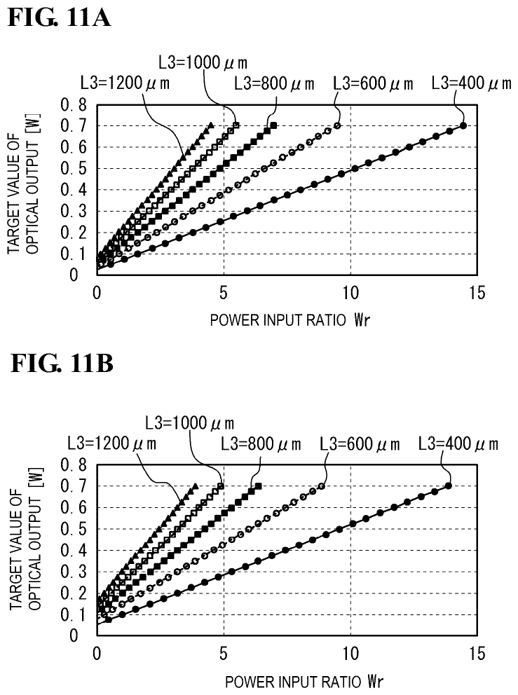

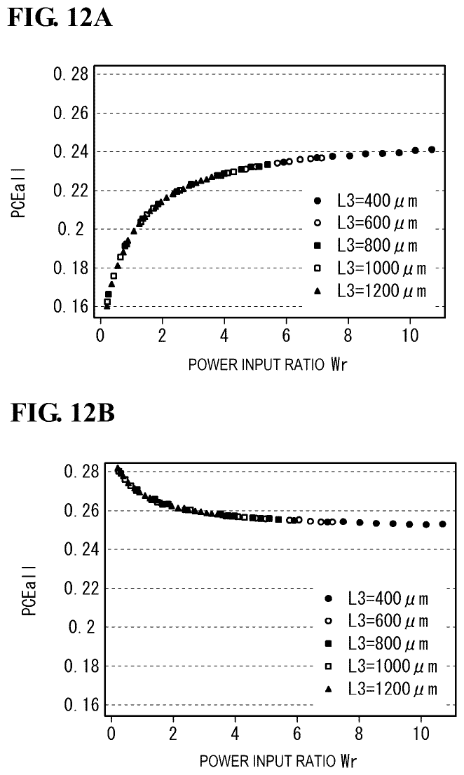

FIG. 12A and FIG. 12B are diagrams illustrating the relationship between the power input ratio Wr and the power conversion efficiency PCEall. The horizontal axis represents the power input ratio Wr. The vertical axis represents the power conversion efficiency PCEall of the entire semiconductor laser element. FIG. 12A shows the embodiment. FIG. 12B shows the comparative example.

As shown in FIG. 12A, in the embodiment, the greater the power input ratio Wr, the higher the power conversion efficiency PCEall becomes. As the resonator length L3 is shorter, for example, 800 μm, 600 μm, or 400 μm, the power input ratio Wr increases and the power conversion efficiency PCEall increases. As shown in FIG. 12B, in the comparative example, the greater the power input ratio Wr, the lower the power conversion efficiency PCEall becomes. In either example, the power conversion efficiency PCEall approaches a certain value (about 0.25) as the power input ratio Wr increases.

When compared at the same power input ratio Wr, the power conversion efficiency PCEall shown in FIG. 12A is lower than the power conversion efficiency PCEall shown in FIG. 12B. As the power input ratio Wr is high, the power conversion efficiency PCEall in FIG. 12A increases, and the power conversion efficiency PCEall in FIG. 12B decreases. The difference in power conversion efficiency PCEall between the embodiment and the comparative example is reduced.

As described above, in the embodiment, the greater the power input ratio Wr, the higher the power conversion efficiency PCEall becomes. In order to make the power input ratio Wr greater than one, the power Wsoa input to the amplification section 12 is made larger than the power Wdfb input to the laser section 10. Specifically, it is only necessary that the area of the mesa 31 in the amplification section 12 is larger than the area of the mesa 31 in the laser section 10. The length L3 and the width W1 of the portion 31a of the mesa 31 and the length L4 and the width W2 of the portion 31b of the mesa 31 are set to appropriate values.

In the following example, appropriate ranges of the length L3 of the portion 31a and the length L4 of the portion 31b of the mesa 31 are determined in accordance with the length (the total length Lt) of the semiconductor laser element 100.

The output Psoa of the emitted light B3 of the amplification section 12 is expressed by Equation (5). The g is a gain per unit length in the amplification section 12. Psoa=Pdfb×exp (g× L4) (5)

By substituting Psoa expressed by Equation (5) into Equation (2), the length L4 is expressed by Equation (6). L4=(1/g) In (Esoa×Wsoa/Pdfb+1) (6)

The power conversion efficiency PCEall and the length L4 are calculated for each total length Lt of the semiconductor laser element 100 and the resonator length L3. In this example, a gain g is set to 15 cm⁻¹.

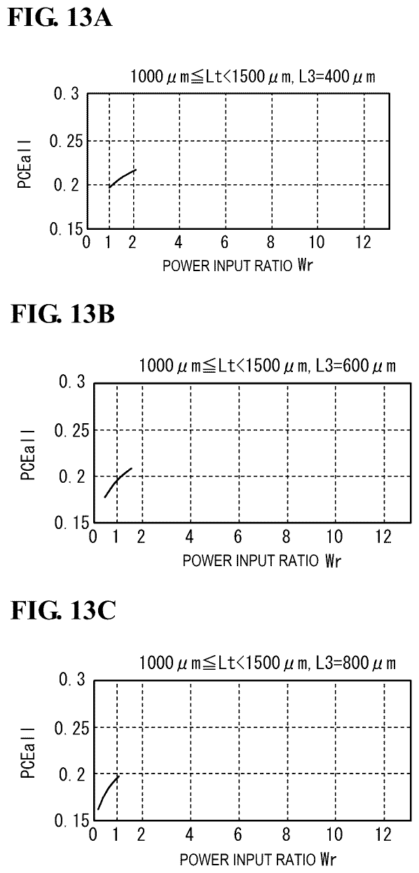

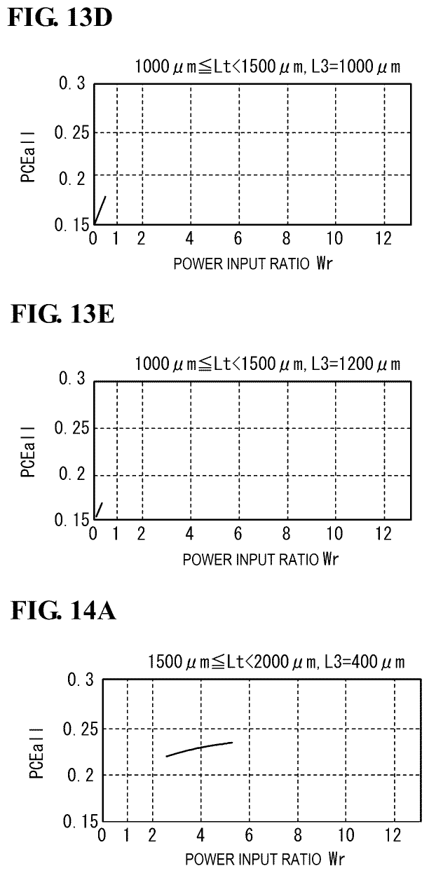

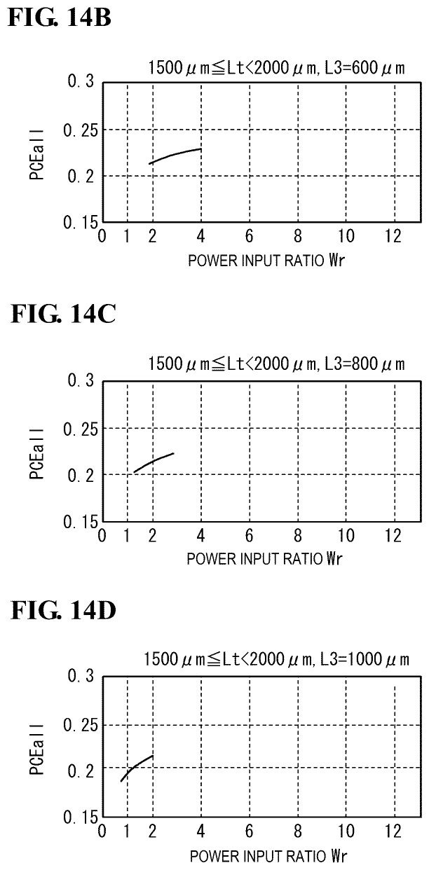

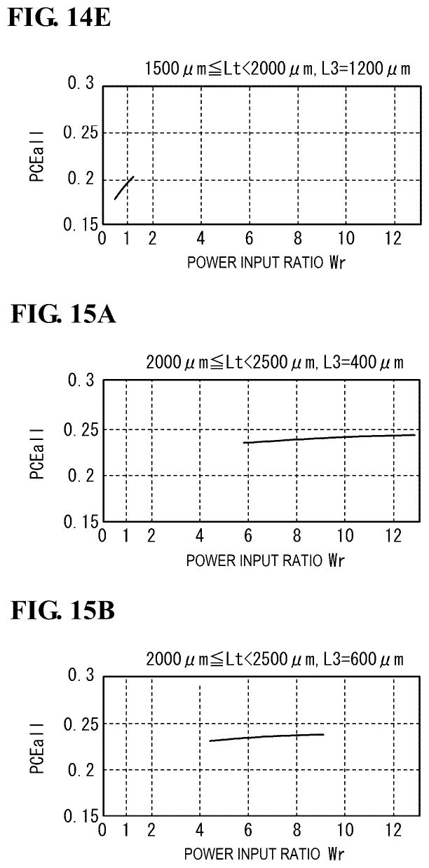

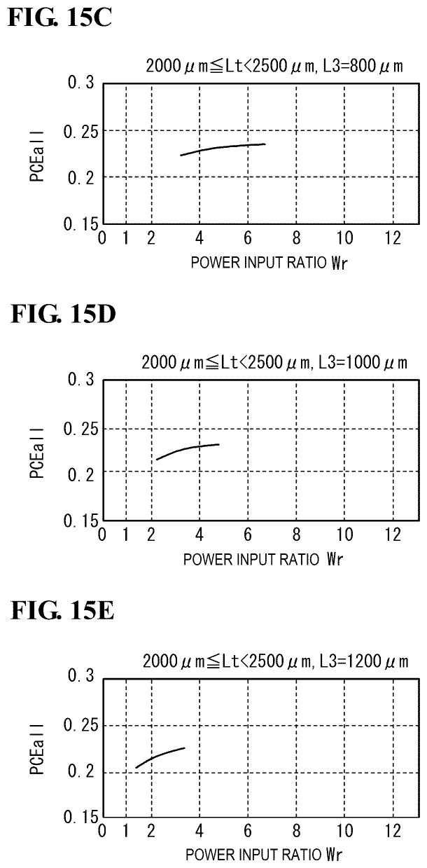

FIG. 13A to FIG. 15E are diagrams illustrating the relationship between the power input ratio Wr and the power conversion efficiency PCEall. The horizontal axis represents the power input ratio Wr. The vertical axis represents the power conversion efficiency PCEall of the entire element. In FIG. 13A to FIG. 13E, the total length Lt is set to 1000 μm or more and less than 1500 μm. The resonator length L3 in FIG. 13A to FIG. 13E is set to 400 μm, 600 μm, 800 μm, 1000 μm, and 1200 μm, respectively. In FIG. 14A to FIG. 14E, the total length Lt is set to be 1500 μm or more and less than 2000 μm. In FIG. 15A to FIG. 15E, the total length Lt is set to 2000 μm or more and less than 2500 μm. In FIG. 14A to FIG. 14E and FIG. 15A to FIG. 15E, the resonator length L3 is set to the same value as that in FIG. 13A to FIG. 13E. The diagram shows the possible ranges of the power input ratio Wr and the power conversion efficiency PCEall.

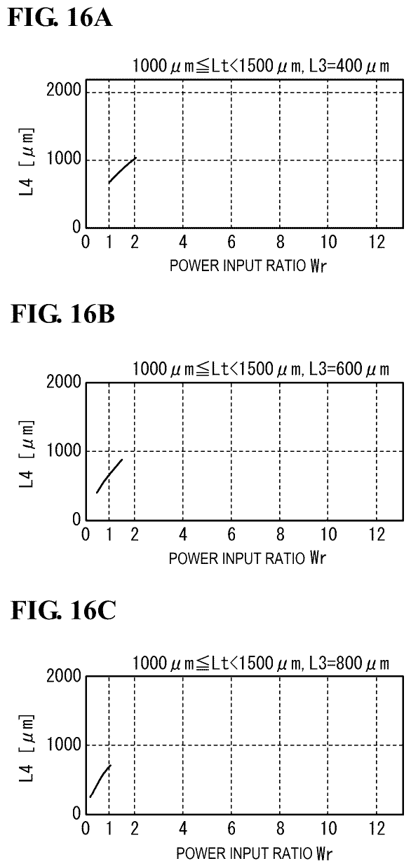

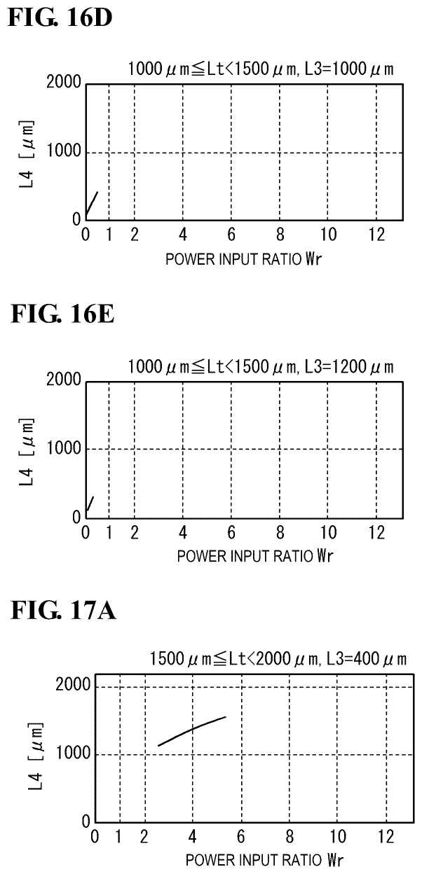

FIG. 16A to FIG. 18E are diagrams illustrating the relationship between the power input ratio Wr and the length L4 of the portion 31b of the mesa 31. The horizontal axis represents the power input ratio Wr. The vertical axis represents the length L4 of the mesa 31 in the amplification section 12. The total length Lt and the resonator length L3 are set in the same ranges as those in FIG. 13A to FIG. 15E. The diagram shows the possible ranges of the power input ratio Wr and the length L4.

As shown in FIGS. 13D and 13E, and FIGS. 16D and 16E, when the total length Lt is in the range of 1000 μm or more and less than 1500 μm and the resonator length L3 is 1000 μm or 1200 μm, the power input ratio Wr is less than 1. As shown in FIG. 13A to FIG. 13C and FIG. 16A to FIG. 16C, when the resonator length L3 is 400 μm, 600 μm, or 800 μm, the power input ratio Wr can be 1 or more. As shown in FIG. 16A, when Wr is greater than 1, the length L4 of the portion 31b is about 700 μm to about 1000 μm.

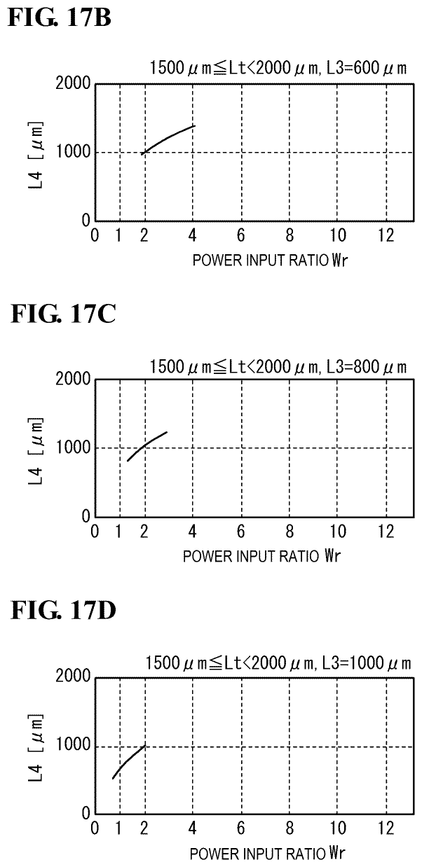

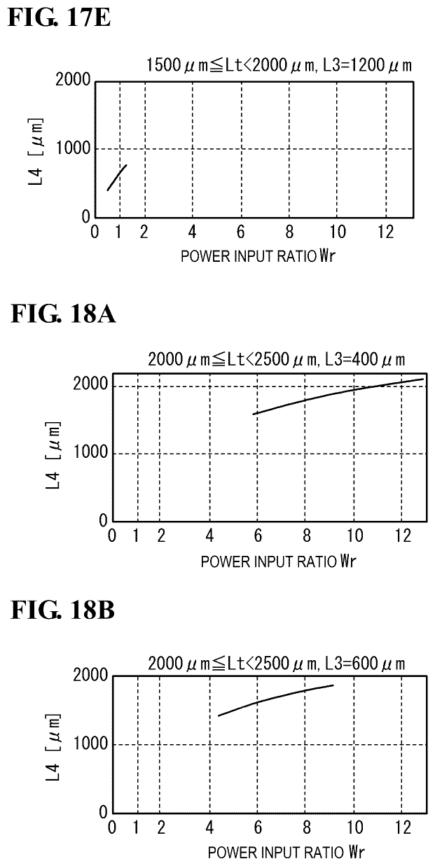

As shown in FIG. 14D and FIG. 14E, and FIG. 17D and FIG. 17E, when the total length Lt is in the range of 1500 μm or more and less than 2000 μm and the resonator length L3 is 1000 μm or 1200 μm, the power input ratio Wr can be less than 1. As shown in FIG. 14A to FIG. 14C and FIG. 17A to FIG. 17C, when the resonator length L3 is 400 μm, 600 μm, or 800 μm, the power input ratio Wr is greater than 1. When Wr is greater than 1, the length L4 of the portion 31b is about 700 μm to about 1500 μm.

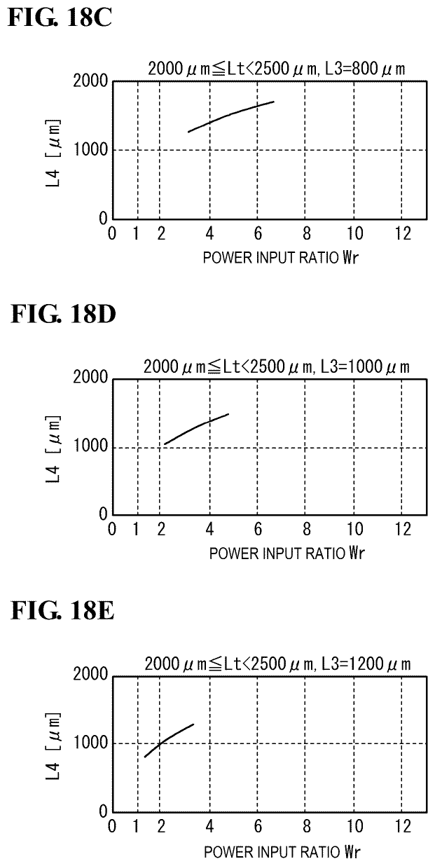

As shown in FIG. 15A to FIG. 15E, and FIG. 18A to FIG. 18E, when the total length Lt is in the range of 2000 μm or more and less than 2500 μm, the power input ratio Wr is greater than 1 regardless of whether the resonator length L3 is between 400 μm to 1200 μm. The length L4 of the portion 31b is about 800 μm to about 2100 μm.

As the total length Lt is longer and the resonator length L3 is shorter, the length L4 of the portion 31b is longer and the power input ratio Wr becomes greater. The power conversion efficiency PCEall is improved. For example, the resonator length L3 may be less than or equal to 0.6 times, less than or equal to 0.5 times, or less than or equal to 0.4 times the total length Lt. When the total length Lt is 1500 μm or more and the resonator length L3 is less than or equal to 0.6 times the total length Lt, the power input ratio Wr becomes greater than 1 (FIG. 14A to FIG. 14C, FIG. 17A to FIG. 17C, FIG. 15A to FIG. 15E, and FIG. 18A to FIG. 18E).

According to the embodiment, as shown in FIG. 1 and FIG. 2, the anti-reflection coating 20 is provided on the end face 11, and the anti-reflection coating 21 is provided on the end face 13. Since the reflected light is less likely to be generated from the end face 11, the influence of the reflected light on the wavelength is reduced. The wavelength of the emitted light B3 is determined by the diffraction grating 35. The wavelength can be controlled stably. Since the variation in wavelength among elements is reduced, the yield is improved.

As shown in FIG. 1, the mesa 31 is provided in the laser section 10 and the amplification section 12. In a plan view, the area of the mesa 31 in the amplification section 12 is larger than the area of the mesa 31 in the laser section 10. The power Wsoa input to the amplification section 12 becomes larger than the power Wdfb input to the laser section 10, and the power input ratio Wr becomes greater than 1. As shown in FIG. 12A, the power conversion efficiency PCEall of the semiconductor laser element 100 increases as the power input ratio Wr increases. It is possible to stabilize the wavelength of light and increase efficiency.

The power input ratio Wr depends on the area ratio of the mesa 31 in the laser section 10 and the amplification section 12. The area of the mesa 31 in the amplification section 12 may be equal to or more than twice, equal to or more than three times, equal to or more than four times, equal to or more than five times, equal to or more than eight times, or equal to or more than ten times the area of the mesa 31 in the laser section 10. When the driving voltage of the laser section 10 and the driving voltage of the amplification section 12 are set to be substantially the same, the power input ratio Wr is also two or more, three or more, four or more, five or more, eight or more, or ten or more according to the area ratio. For example, the area of the mesa 31 in the amplification section 12 is set to be equal to or more than four times the area of the mesa 31 in the laser section 10. In the example of FIG. 12B, when the power input ratio Wr is four or more, the power conversion efficiency PCEall is about 0.23 or more.

The length L4 of the mesa 31 in the amplification section 12 may be larger than the length L3 of the mesa 31 in the laser section 10. The width W2 of the mesa 31 in the amplification section 12 may be larger than the width W1 of the mesa 31 in the laser section 10. When the length L4 is larger than the length L3 and the width W2 is larger than the width W1, the area of the mesa 31 in the amplification section 12 is larger than the area of the mesa 31 in the laser section 10. The power input ratio Wr becomes greater than one, and the power conversion efficiency PCEall is improved. Even when the length L4 is smaller than the length L3, the area of the portion 31b is larger than the area of the portion 31a when the width W2 is sufficiently larger than the width W1. Even when the width W2 is smaller than the width W1, the area of the portion 31b is larger than the area of the portion 31a when the length L4 is sufficiently larger than the length L3.

The emitted light B1 in the laser section 10 passes through the anti-reflection coating 20 and is emitted to the outside of the end face 11, resulting in loss. In order to reduce the loss, it is only necessary to downsize the laser section 10 to reduce the emitted light B1. However, when the resonator length L3 is reduced, the laser section 10 is less likely to stably operate as a DFB laser element. When the resonator length L3 is long, the loss of the emitted light B1 increases, and the multimode may oscillate. For example, the resonator length L3 is set to 400 μm to 1200 μm. By setting the resonator length L3 to 400 μm or more, the laser section 10 stably operates as a DFB laser element. By setting the resonator length L3 to 1200 μm or less, the loss is reduced and the multimode oscillation is less likely to occur.

As shown in FIG. 11A, at a constant optical output, the shorter the resonator length L3, the greater the power input ratio Wr. As shown in FIG. 10A, for a constant optical output, the shorter the resonator length L3, the higher the power conversion efficiency PCEall. For example, the resonator length L3 may be 400 μm or more, 600 μm or less, 800 μm or less, 1000 μm or less, or 1200 μm or less.

The resonator length L3 may be, for example, less than or equal to 0.6 times, less than or equal to 0.5 times, less than or equal to 0.4 times, or less than or equal to 0.3 times the total length Lt of the semiconductor laser element 100. When the total length Lt is 1500 μm or more, the resonator length L3 is set to less than or equal to 0.6 times of the total length Lt, that is, 900 μm or less. As shown in FIG. 14A to FIG. 14C and FIG. 17A to FIG. 17C, the power input ratio Wr becomes greater than one. When the total length Lt is 2000 μm or more, the resonator length L3 is set to less than or equal to 0.6 times of the total length Lt, that is, 1200 μm or less. As shown in FIG. 15A to FIG. 15E and FIG. 18A to FIG. 18E, the power input ratio Wr becomes greater than one. When the total length Lt is 2000 μm or more and the resonator length is 600 μm or less, the power input ratio Wr becomes greater than 4. In the amplification section 12, the length L4 of the mesa 31 becomes long, and the power conversion efficiency PCEall becomes high. However, in order to reduce the size of the semiconductor laser element 100, it is preferable to limit the total length Lt. The total length Lt is, for example, 2500 μm or less, or 3000 μm or less.

The active region in the semiconductor laser element 100 is the mesa 31. As shown in FIG. 2, the mesa 31 includes the active layer 36 and extends into the laser section 10 and the amplification section 12. As shown in FIG. 1, the portion 31a of the mesa 31 is located in the laser section 10. The portion 31b of the mesa 31 is located in the amplification section 12. In a plan view, the area of the portion 31b is larger than the area of the portion 31a. The power Wsoa input to the portion 31b is larger than the power Wdfb input to the portion 31a. The power input ratio Wr becomes greater than one, and the power conversion efficiency PCEall becomes high.

As shown in FIG. 3A and FIG. 3B, the n-type substrate 30, the i-type active layer 36, the p-type cladding layer 40, and the contact layer 42 are stacked to form the mesa 31. The mesa 31 includes a pin junction. A current can be injected into the active layer 36 of the mesa 31. The light is laser-oscillated in the laser section 10, and the light is amplified in the amplification section 12.

The embedding layer 39 is provided on each of two sides of the mesa 31. The embedding layer 39 includes the n-type semiconductor layer 46 and the p-type semiconductor layer 44. A pnpn junction is formed on each of two sides of the mesa 31. Due to the current constriction structure, the current is likely to flow into the mesa 31 and less likely to flow out of the mesa 31. The power conversion efficiency PCEall is increased by intensively flowing the current to the mesa 31.

As shown in FIG. 1, the electrode 23 overlaps the portion 31a of the mesa 31. The electrode 24 overlaps the portion 31b of the mesa 31. As shown in FIG. 2, the electrode 22 is provided on the rear surface of the substrate 30. The current flows in the Z-axis direction. The amount of current and power input to the mesa 31 depends on the area of the mesa 31. By making the area of the portion 31b larger than the area of the portion 31a, the power input ratio Wr becomes greater than one. The power conversion efficiency PCEall is increased.

As shown in FIG. 11A, the higher the optical output, the greater the power input ratio Wr. As shown in FIG. 10A, the higher the optical output, the higher the power conversion efficiency PCEall. The optical output of the light B3 after amplification by the amplification section 12 may be, for example, 200 m W or more, 300 mW or more, or 500 mW or more. The semiconductor laser element 100 functions as a light source with high efficiency and high output.

The reflectance of an interface between the semiconductor layer and air is about 30% with respect to light having a wavelength of around 1300 nm. The reflectance of the anti-reflection coating 20 and the anti-reflection coating 21 is lower than the reflectance at the interface between the semiconductor and air, and is 30% or less, 10% or less, or 1% or less.

Although the embodiments of the present disclosure have been described in detail, the present disclosure is not limited to the specific embodiments, and various modifications and changes can be made within the scope of the gist of the present disclosure described in the claims.

What is claimed is:

1. A semiconductor laser element comprising:
a laser section configured to cause light to perform laser oscillation;
an amplification section configured to amplify the light;
an active region extending to the laser section and the amplification section;
a first anti-reflection coating provided on an end face of the laser section opposite to the amplification section with respect to the laser section; and
a second anti-reflection coating provided on an end face of the amplification section opposite to the laser section with respect to the amplification section,
wherein, in a plan view, an area of the active region in the amplification section is larger than an area of the active region in the laser section.

2. The semiconductor laser element according to claim 1,
wherein the area of the active region in the amplification section is equal to or more than four times the area of the active region in the laser section.

3. The semiconductor laser element according to claim 1,
wherein the active region in the amplification section is longer than the active region in the laser section, and
wherein a width of the active region in the amplification section is greater than a width of the active region in the laser section.

4. The semiconductor laser element according to claim 1,
wherein the laser section has a length of 400 μm to 1200 μm.

5. The semiconductor laser element according to claim 1,
wherein a length of the active region in the laser section is less than or equal to 0.6 times a length of the semiconductor laser element.

6. The semiconductor laser element according to claim 1, further comprising:
an active layer provided in the laser section and the amplification section,
wherein the active region is a mesa, and
wherein the mesa includes an active layer and extends to the laser section and the amplification section.

7. The semiconductor laser element according to claim 6, further comprising:
a first semiconductor layer, the active layer, and a second semiconductor layer that are stacked in this order in the laser section and the amplification section,
wherein the first semiconductor layer has a first conductivity type,
wherein the second semiconductor layer has a second conductivity type,
wherein the first semiconductor layer and the active layer are configured to form the mesa, and
wherein the second semiconductor layer is provided above the mesa.

8. The semiconductor laser element according to claim 6, further comprising:
an embedding layer provided on each of two sides of the mesa in the laser section and the amplification section.

9. The semiconductor laser element according to claim 6, further comprising:
a first electrode provided in the laser section and overlapping a portion of the mesa provided in the laser section; and
a second electrode provided in the amplification section and overlapping a portion of the mesa provided in the amplification section.

10. The semiconductor laser element according to claim 1,
wherein the light amplified by the amplification section has an output of 200 mW or more.

11. A method of manufacturing a semiconductor laser element, the method comprising:
designing a laser section configured to cause light to perform laser oscillation and an amplification section configured to amplify the light;
forming the laser section and the amplification section based on the designing of the laser section and the amplification section;
forming a first anti-reflection coating on an end face of the laser section opposite to the amplification section with respect to the laser section;
forming a second anti-reflection coating on an end face of the amplification section opposite to the laser section with respect to the amplification section,
wherein the laser section and the amplification section include an active region, and
wherein the designing is performed such that a power input to the active region in the amplification section is larger than a power input to the active region in the laser section.
